(19) United States
(12) Patent Application Publication
(10) Pub. No.: US 2010/0244260 A1
(43) Pub. Date: Sep. 30, 2010

(54) SEMICONDUCTOR DEVICE AND METHOD FOR FABRICATING THE SAME

(75) Inventor: Toru HINOMURA, Toyama (JP)

Correspondence Address: MCDERMOTT WILL & EMERY LLP, 600 13TH STREET, NW, WASHINGTON, DC, 20005-3096, US

(73) Assignee: Panasonic Corporation, Osaka (JP)

(21) Appl. No.: 12/795,141

(22) Filed: Jun. 7, 2010

Related U.S. Application Data
(63) Continuation of application No. PCT/JP2009/003369, filed on Jul. 16, 2009.

(30) Foreign Application Priority Data
Oct. 9, 2008 (JP) 2008-262809

(51) Int. Cl. H01L 23/532; H01L 21/768

(52) U.S. Cl. 257/751; 438/643; 257/E23.157; 257/E21.584

(57) ABSTRACT

A semiconductor device includes: a first insulting film formed on a semiconductor substrate; a contact including a conductive film buried in the first insulating film to reach the semiconductor substrate; and a first barrier layer including a high melting point metal, formed between the semiconductor substrate and the conductive film and between the first insulating film and the conductive film. The device also includes a second barrier layer lower in moisture permeability than the first barrier layer, formed between the first barrier layer and the conductive film.

### CROSS-REFERENCE TO RELATED APPLICATION

This is a continuation of PCT International Application PCT/JP2009/003369 filed on Jul. 16, 2009, which claims priority to Japanese Patent Application No. 2008-262809 filed on Oct. 9, 2008. The disclosures of these applications including the specifications, the drawings, and the claims are hereby incorporated by reference in their entirety.

### BACKGROUND

With miniaturization of semiconductor devices, the resistance of contacts for connecting diffusion layers, gates, and the like to interconnect layers has increased so prominently that it has come to affect device characteristics.

A related art method for forming contacts will be described hereinafter. FIGS. 9-12 are schematic cross sectional views illustrating a contact formation method.

In the step shown in FIG. 9, first, a semiconductor substrate 1 is prepared. For the semiconductor substrate 1, formation of element isolation (not shown), impurity implantation, and the like are performed, followed by formation of an intermetallic compound layer 2. A first insulating film 3 is then formed to cover the semiconductor substrate 1 including the intermetallic compound layer 2. A through hole 4 (contact hole) is then formed through the first insulating film 3 to reach the intermetallic compound layer 2 or a gate not shown formed on the semiconductor substrate 1 by lithography, dry etching, wet etching, and the like.

The surface of the intermetallic compound layer 2 exposed at the bottom of the through hole 4 is then cleaned by argon sputtering or chemical dry etching. Thereafter, as shown in FIG. 10, a barrier layer 7 constructed of a titanium layer 5 and a titanium nitride layer 6 covering the titanium layer 5 is formed to cover the inner wall and bottom of the through hole 4 by physical vapor deposition (PVD) or chemical vapor deposition (CVD).

Subsequently, a tungsten nucleation layer 8 is formed by CVD with silane (SiH₄) reduction of tungsten hexafluoride (WF₆) to cover the titanium nitride layer 6. A tungsten layer 9 is then formed by CVD to fill the space left in the through hole 4.

Thereafter, as shown in FIG. 11, portions of the titanium layer 5, the titanium nitride layer 6, the tungsten nucleation layer 8, and the tungsten layer 9 protruding from the through hole 4 are removed by chemical mechanical polishing (CMP), thereby to obtain a contact 10 inside the through hole 4.

A structure shown in FIG. 12 is then formed. First, a second insulating film 11 and then a third insulating film 12 are formed sequentially on the surface of the first insulating film 3 and the surface of the contact 10. Thereafter, an opening is formed through the second and third insulating films 11 and 12 to expose the top surface of the contact 10, and then a first interconnect layer 16 constructed of a second barrier layer 13, a seed layer 14, and a copper layer 15 is formed inside the opening. This may be performed using any of lithography, dry etching, wet etching, PVD, CVD, electrolytic plating, CMP, and the like appropriately. Although not shown, another insulating film, an upper connection hole, and an upper interconnect layer are also formed.

The barrier layer that is made of a high melting point metal is highest in resistivity among the materials constituting the contact. Specifically, while the resistivity of tungsten as one of the materials of the contact plug is about 5.3 μΩcm in its bulk state, the resistivity of the titanium as a typical barrier material is about 43 μΩcm in its bulk state. Moreover, the resistivity is higher when a material is formed into a thin film having a thickness of about 10 to 100 nm used for fabrication of semiconductor devices than when it is in a bulk state. Specifically, while the resistivity of tungsten is about 10 to 20 μΩcm and that of the tungsten nucleation layer is about 100 to 200 μΩcm, the resistivity of titanium nitride used as the barrier layer is about 600 to 800 μΩcm. Accordingly, in order to reduce the contact resistance to cope with miniaturization of semiconductor devices, thinning of the barrier layer that is a high-resistance layer is indispensable.

However, when the barrier layer is thinned, the barrier property thereof becomes insufficient, and this causes increase in contact resistance.

To solve the above problem, a barrier layer formation technique has been developed, as described in Japanese Patent No. 3592451 (Document 1), in which a barrier layer made of a high melting point metal is densified by heat treatment in a specific gas atmosphere, to form a barrier layer capable of preventing diffusion of an element even though being thin. According to the method for fabricating a semiconductor device described in Document 1, by annealing a semiconductor substrate after formation of a barrier layer made of a high melting point metal in an atmosphere of a hydrogen compound gas, or an organic compound gas, containing a III-V group (13-15 group in the current IUPAC notation) element, a barrier layer dense compared with related art ones can be obtained.

A variety of contact formation techniques have also been developed to cope with the recent miniaturization of semiconductor devices. For example, in formation of the first insulating film 3 shown in FIGS. 9-12, it is necessary to fill inter-gate gaps, which have become narrow with the miniaturization, without any void formed therein. To achieve this, in place of general deposition of an insulating film by plasma CVD, deposition of ozone tetraethyl orthosilicate (O₃-TEOS) by thermal CVD, which is superior in filling capability, has been adopted. However, while an O₃-TEOS film exhibits good filling capability, it is known to have high hygroscopicity, absorbing a larger amount of moisture than a plasma CVD film.

As another problem, to fill a fine through hole with tungsten, it is necessary to form a tungsten nucleation layer uniformly inside the through hole. It is however difficult to achieve this by CVD.

To solve the above problem, as described in Japanese Patent Publication No. 2002-38271 (Document 2) and Japanese Patent No. 4032872 (document 3), atomic layer deposition (ALD) has been increasingly adopted, in which a reducing gas and a tungsten-containing gas represented by tungsten hexafluoride are fed alternately. Moreover, by using a boron-hydrogen compound gas such as diborane (B₂H₆), in place of silane generally used, as the reducing gas, a boron-containing tungsten nucleation layer smoother than related art ones can be deposited in its amorphous state low in crystallinity. With this formation, the tungsten nucleation layer, which is high in resistivity compared with bulk tungsten, can be thinned, and thus the contact resistance can be reduced.

### SUMMARY

The present inventors have found that when Documents 2 and 3 are combined with Document 1, a new problem as follows arises. That is, for the structure described with reference to FIGS. 9-12, when an O₃-TEOS film is used as the first insulating film 3 and a boron-containing tungsten layer formed using diborane as the reducing gas is used as the tungsten nucleation layer 8, the contact resistance increases, as will be described below in detail.

FIG. 13 shows the results of study on difference in contact resistance value occurring with difference in the formation of the tungsten nucleation layer 8 in the through hole 4, in the structure described in Document 1 in which an O₃-TEOS film is used as the first insulating film 3. In FIG. 13, A represents resistance values in the case where a tungsten film formed with silane gas as the reducing gas is used as the tungsten nucleation layer 8, and B represents resistance values in the case where a boron-containing tungsten film formed with diborane gas as the reducing gas is used as the tungsten nucleation layer 8. Note that the heat treatment for densifying the barrier layer described in Document 1 is performed using the reducing gas used during the deposition of the tungsten nucleation layer 8 for both cases. Note also that the cumulative frequency as the y-axis refers to the indicator of the frequency distribution of contact resistance values, which may translate to the percentage.

As is apparent from FIG. 13, the contact resistance increases and the variations thereof increases in the case of the tungsten nucleation layer with diborane reduction (B) compared with the case of the tungsten nucleation layer with silane reduction (A).

FIG. 14 shows the results of study on difference in contact resistance value with difference in the formation of the first insulating film 3, in which diborane gas is used as the heat treatment atmosphere and a boron-containing tungsten film formed with diborane reduction is used as the tungsten nucleation layer 8. In FIG. 14, A represents resistance values in the case where a general plasma TEOS (P-TEOS) film is used as the first insulating film 3, and B represents resistance values in the case where an O₃-TEOS film according to the technique coping with miniaturization is used as the first insulating film 3.

As shown in FIG. 14, while the contact resistance does not increase in the case A as the combination of the boron-containing tungsten film and the P-TEOS film, it increases in the case B as the combination of the boron-containing tungsten film and the O₃-TEOS film.

As described above, the present inventors have found that the contact resistance increases when an O₃-TEOS film is used as the first insulating film 3 and diborane gas is used as the heat treatment atmosphere and as the reducing gas during deposition of the tungsten nucleation layer 8 in the structure described in Document 1.

FIG. 15 shows the results of study on contact resistance values observed when the titanium nitride layer 6 constituting the barrier layer 7 is thickened. That is, FIG. 15 shows the contact resistance values when an O₃-TEOS film is used as the first insulating film 3 and diborane is used as the heat treatment atmosphere and as the reducing gas during deposition of the tungsten nucleation layer 8 in the structure described in Document 1, in which B represents the case where the thickness of the titanium nitride layer 6 is 2.6 nm and C represents the case where it is 5.0 nm.

As is apparent from FIG. 15, while the contact resistance increases prominently in the case B, increase in contact resistance is reduced in the case C. This indicates that increase in contact resistance and variations thereof can be reduced by thickening the titanium nitride film 6.

However, compared with case A in FIG. 15, in which the titanium nitride 6 having the same thickness (2.6 nm) as in the case B and the tungsten nucleation layer 8 with silane reduction are combined, increase in contact resistance value is also observed in the case C.

It is therefore difficult to cope with the miniaturization of semiconductor devices and the resultant increase in contact resistance value by thickening the barrier layer.

In view of the new problem described above found by the present inventors, proposed is a semiconductor device having a contact with low resistance and high yield while avoiding degradation in device characteristics, in which increase in contact resistance value occurring with use of a boron-hydrogen compound such as diborane is suppressed, and the barrier layer and the tungsten nucleation layer are thinned, and a method for fabricating such a semiconductor device, which will be described below.

The present inventors have examined causes for the increase in contact resistance occurring with the combination of an O₃-TEOS film and use of diborane as follows.

First, it is known that a boron-hydrogen compound gas such as diborane has high reactivity with water and that boric acid is generated by reaction of diborane with water. Also, an O₃-TEOS film occludes a large amount of moisture compared with a P-TEOS film. Therefore, moisture occluded by the O₃-TEOS film permeates through the titanium nitride layer as the barrier layer and reacts with diborane gas used as the heat treatment atmosphere and for deposition of the tungsten nucleation layer, resulting in deposition failure in the tungsten nucleation layer. Caused by the deposition failure, the contact resistance increases.

However, the above cause may not be limited to the case of using an O₃-TEOS film. That is, an insulating film generally occludes moisture, and the amount of occluded moisture depends on the type of the film, the film formation method, and the like. Although the amount of occluded moisture may be small compared with an O₃-TEOS film that occludes much, other insulating films such as those formed by plasma CVD, application, and the like also occlude moisture. Accordingly, in such cases, also, increase in contact resistance may occur caused by reaction between moisture and a boron-hydrogen compound.

In general, for contact formation, degassing of removing moisture from a semiconductor substrate by heating the semiconductor substrate is performed before a process of cleaning the surface of an intermetallic compound layer at the bottom of a through hole. In this degassing, however, with shrinking of the size of the through hole along with the miniaturization of the semiconductor device, the efficiency of moisture removal from the through hole decreases, and thus moisture tends to remain in the through hole at the time of contact formation.

Such residual moisture also serves as a cause of increasing the contact resistance since it easily reacts with diborane gas during heat treatment in a diborane atmosphere or during deposition of a tungsten nucleation layer with diborane reduction. This also implies that the increase in contact resistance with use of a boron-hydrogen compound such as diborane occurs irrespective of use of an O₃-TEOS film.

The reason why increase in contact resistance can be reduced by thickening the titanium nitride layer is that the thick titanium nitride layer can reduce permeation of moisture detached from the O₃-TEOS film, making it difficult for moisture to react with diborane. However, as shown in FIG. 15, thickening of the titanium nitride layer itself as the barrier layer causes increase in contact resistance.

Based on the study and examination described above, the semiconductor device of the present disclosure includes: a first insulting film formed on a semiconductor substrate, a contact hole being formed through the first insulating film to reach the semiconductor substrate; a contact having a conductive film filling the contact hole; a first barrier layer including a high melting point metal, formed between the semiconductor substrate and the conductive film and between the first insulating film and the conductive film; and a second barrier layer lower in moisture permeability than the first barrier layer, formed between the first barrier layer and the conductive film.

With the semiconductor device described above, provided with the second barrier layer less prone to moisture permeation than the first barrier layer, increase in contact resistance is suppressed, which otherwise occurs under influence of moisture originating from the first insulating film and the like. In this configuration, it is unnecessary to thick the first barrier layer, and this is also advantageous in suppressing increase in contact resistance. Note that the expression that the contact reaches the semiconductor substrate includes cases that the contact reaches an impurity layer, an intermetallic compound layer, a gate electrode, and the like formed on the semiconductor substrate.

The device may further include: a second insulting film formed on the first insulating film; and an interconnect formed through the second insulting film to be connected to the contact.

The second barrier layer is preferably a film including a compound of the high melting point metal and silicon.

Such a film is low in moisture permeability and thus useful as the second barrier layer.

A layer including a compound of a major component of the conductive film and boron is preferably formed between the second barrier layer and the conductive film.

With formation of such a film, the contact hole can be filled with the conductive film reliably.

The major component of the conductive film is preferably tungsten. Tungsten is useful as the material for forming the contact.

The first barrier layer preferably includes at least one of titanium, tantalum, ruthenium, and tungsten or a nitride thereof. Such substances are useful as the material of the first barrier layer.

There may be a position where the total thickness of the first barrier layer and the second barrier layer is less than 5.0 nm.

With formation of the second barrier layer low in moisture permeability, moisture permeation can be sufficiently reduced even when the total thickness of the first and second barrier layers is thus small, and this is useful for suppressing increase in contact resistance.

The first insulating film may contain moisture. In other words, moisture may be contained in the first insulating film, not only during the fabrication process, but also after fabrication of the semiconductor device. In such a case, the effect of the technique of the present disclosure will be exerted more eminently.

The diameter of the contact may be 60 nm or less. The smaller the contact is, the more difficult it is to remove moisture from inside the contact hole. However, the effect of the technique of the present disclosure is exerted eminently even when the diameter of the contact is 60 nm or less.

The method for fabricating a semiconductor device of the present disclosure includes the steps of: (a) forming a first insulting film on a semiconductor substrate; (b) forming a contact hole through the first insulating film to reach the semiconductor substrate; (c) forming a first barrier layer including a high melting point metal to cover the bottom and sidewall of the contact hole; d) forming a second barrier layer lower in moisture permeability than the first barrier layer to cover the first barrier layer; and (e) filling the contact hole with a conductive film after the step (d).

Transistors and the like may be formed on the semiconductor substrate. According to the method for fabricating a semiconductor device described above, in which the second barrier layer lower in moisture permeability than the first barrier layer is formed on the first barrier layer, increase in contact resistance, which may occur under influence of moisture originating from the semiconductor substrate and the like, can be suppressed during fabrication of a semiconductor device. By employing this method, the semiconductor device of the present disclosure can be fabricated.

The second barrier layer is preferably a film including a compound of the high melting point metal and silicon. Such a film is low in moisture permeability and thus useful as the second barrier layer.

The second barrier layer is preferably formed by heat-treating the first barrier layer in a silicon-containing hydrogen compound atmosphere. The second barrier layer may be formed in this way.

The method may further include the step of (f) forming a layer including a compound of a major component of the conductive film and boron on the second barrier layer, between the step (d) and the step (e).

With formation of such a film, the contact hole can be filled with the conductive film more reliably.

The step (d) and the step (f) are preferably performed while keeping the semiconductor substrate from exposure to the atmosphere. By performing these steps in this way, it is possible to prevent the second barrier layer and the layer made of a compound of a major component of the conductive layer and boron from adsorbing moisture in the atmosphere, and this is effective in suppressing increase in contact resistance.

The major component of the conductive film is preferably tungsten.

The first barrier layer preferably includes at least one of titanium, tantalum, ruthenium, and tungsten or a nitride thereof.

The above substances are specific examples of the material of the first barrier layer.

There may be a position where the total thickness of the first barrier layer and the second barrier layer is less than 5.0 nm.

By using a film low in moisture permeability as the second barrier layer, moisture permeation can be sufficiently reduced even with such a thin barrier layer.

The first insulating film may contain moisture.

The first insulating film may be high in hygroscopicity compared with the second insulating film.

The diameter of the contact may be 60 nm or less.

In the above individual cases, the effect of suppressing increase in contact resistance can be exerted eminently.

In the step (d), the semiconductor substrate is preferably held at a temperature in a predetermined temperature range for one minute or less.

Heat treatment for about one minute maximum is sufficient for formation of the second barrier layer. If the treatment is continued longer, the second barrier layer will have an excessive thickness, causing increase in contact resistance. Therefore, treatment for one minute or less is advisable.

The predetermined temperature range is preferably from 100° C. to less than 450° C. A temperature of 450° C. or higher may possibly degrade the characteristics of transistors and the like provided on the semiconductor substrate. A temperature lower than 100° C. will cause failure in sufficient formation of the second barrier layer. Therefore, the temperature range from 100° C. to less than 450° C. is advisable.

As described above, according to the semiconductor device and the method for fabricating the same of the present disclosure, even when a boron-containing tungsten film is used as the nucleation layer for formation of a contact and thinned, increase in contact resistance due to reaction with moisture can be suppressed. Also, the barrier layer can be thinned, and this can also suppress increase in contact resistance. Accordingly, a semiconductor device having a low-resistance contact can be attained.

### BRIEF DESCRIPTION OF THE DRAWINGS

FIG. 1 is a schematic cross-sectional view illustrating step by step an illustrative semiconductor device and its fabrication process in an embodiment of the present disclosure.

FIG. 2 is a schematic cross-sectional view illustrating step by step, following FIG. 1, the illustrative semiconductor device and its fabrication process.

FIG. 3 is a schematic cross-sectional view illustrating step by step, following FIG. 2, the illustrative semiconductor device and its fabrication process.

FIG. 4 is a schematic cross-sectional view illustrating step by step, following FIG. 3, the illustrative semiconductor device and its fabrication process.

FIG. 5 is a schematic cross-sectional view illustrating step by step, following FIG. 4, the illustrative semiconductor device and its fabrication process.

FIG. 6 is a view showing contact resistance values of a comparative example and a semiconductor device of the present disclosure.

FIGS. 7(a) and 7(b) are views showing dependence of a junction leakage current on nucleation film thickness in a comparative example and a semiconductor device of the present disclosure.

FIG. 8 is a view showing contact resistance values of a comparative example and a semiconductor device of the present disclosure.

FIG. 9 is a schematic cross-sectional view illustrating step by step a related art semiconductor device and its fabrication process.

FIG. 10 is a schematic cross-sectional view illustrating step by step, following FIG. 9, the related art semiconductor device and its fabrication process.

FIG. 11 is a schematic cross-sectional view illustrating step by step, following FIG. 10, the related art semiconductor device and its fabrication process.

FIG. 12 is a schematic cross-sectional view illustrating step by step, following FIG. 11, the related art semiconductor device and its fabrication process.

FIG. 13 is a view showing contact resistance values, particularly exhibiting difference in contact resistance value with difference in nucleation layer.

FIG. 14 is a view showing contact resistance values, particularly exhibiting difference in contact resistance value with difference in insulating film.

FIG. 15 is a view showing contact resistance values, particularly exhibiting difference in contact resistance value with difference in nucleation layer and difference in barrier layer thickness.

### DETAILED DESCRIPTION

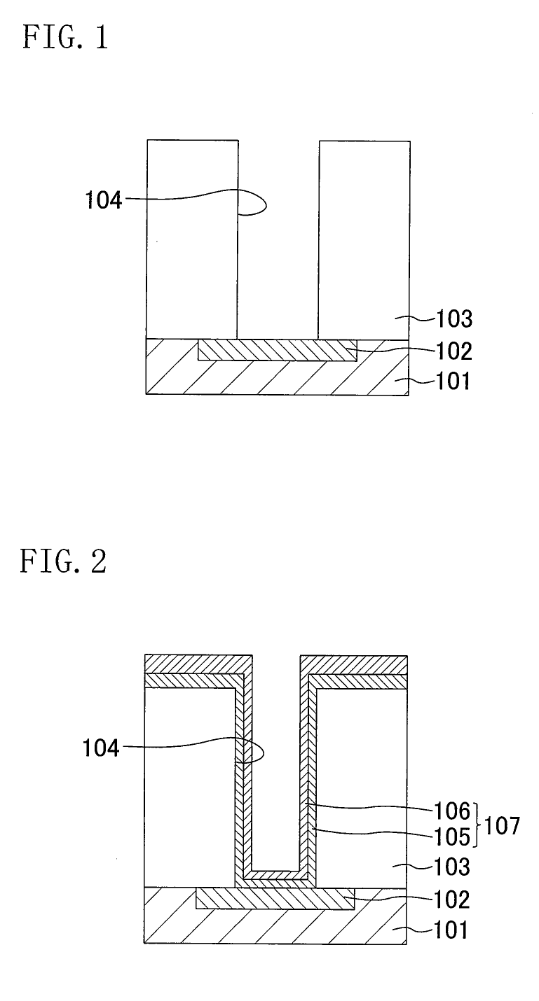

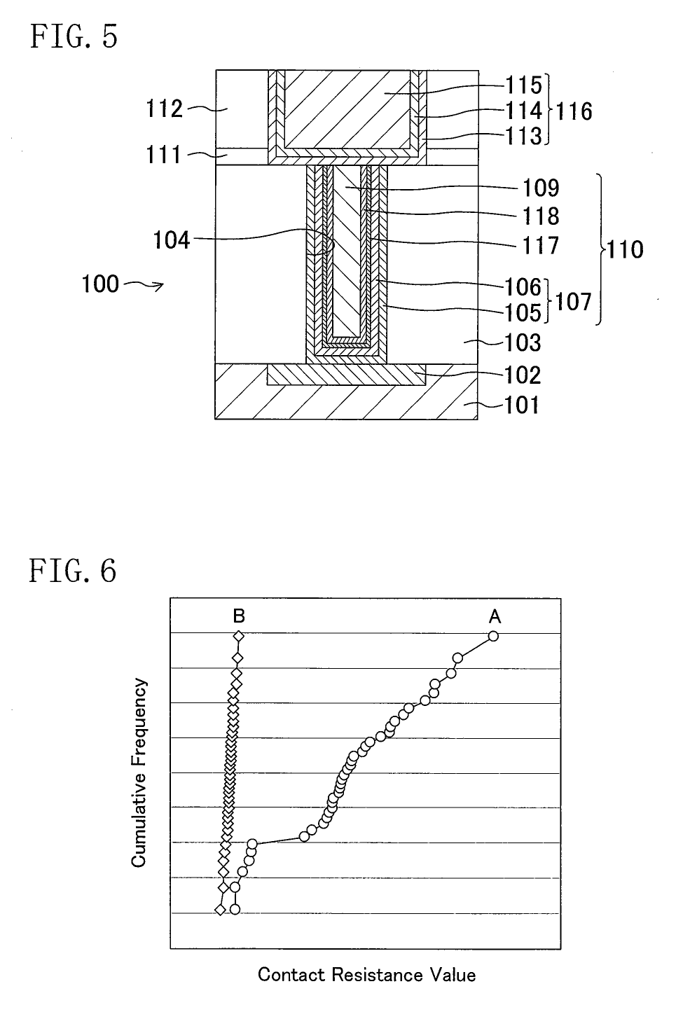

A semiconductor device and a method for fabricating the same of an embodiment of the present disclosure will be described hereinafter with reference to the accompanying drawings. FIGS. 1-4 are schematic cross-sectional views showing process steps for fabricating an illustrative semiconductor device 100 of this embodiment shown in FIG. 5. It should be noted that the drawings and the shapes, materials, sizes, and the like of components to be specified hereinbelow are mere illustration of desirable examples and not intended to limit the present disclosure, which can therefore be changed as appropriate within the range not departing from the technical gist of the disclosure.

In the step in FIG. 1, first, a semiconductor substrate 101 is prepared. The semiconductor substrate 101 has an intermetallic compound layer 102 formed thereon after having undergone steps such as formation of element isolation (not shown) and impurity implantation. Assume that the semiconductor substrate 101 also has elements such as transistors having gate electrodes formed thereon although detailed illustration of such elements is omitted.

Thereafter, a first insulating film 103 is deposited on the semiconductor substrate 101 including the intermetallic compound layer 102. A through hole 104 (contact hole) is then formed through the first insulating film 103 to reach the intermetallic compound layer 2 by lithography, dry etching, wet etching, and the like. The through hole 104 may be formed to reach a gate electrode (not shown) of a transistor in place of the intermetallic compound layer 2.

The intermetallic compound layer 2 is a layer made of a compound containing one or more metal elements and silicon element. As the metal element(s), one of, or a combination of some of, cobalt, nickel, germanium, platinum, and the like, may be used.

The first insulating film 103 may be of a single-layer structure made of a single film as in FIG. 1, or may be of a multilayer structure made of two or more kinds of insulating films. Whichever structure is used, an effect be described later will be attained. An O₃-TEOS film is a typical example of the film species constituting the first insulating film 103, with which the effect is especially remarkable. However, insulating films made of P-TEOS, phosphosilicate glass (PSG), boron phosphosilicate glass (BPSG), non-doped silicate glass (NSG), and fluorosilicate glass (FSG), and multilayer films of any of these films may also be used.

The first insulating film 103 can be formed by thermal CVD, plasma CVD, application, and the like.

The step shown in FIG. 2 is then executed. First, the surface of the intermetallic compound layer 102 exposed at the bottom of the through hole 104 is cleaned by argon sputter etching or chemical etching. Thereafter, a first barrier layer 107 constructed of a titanium layer 105 and a titanium nitride layer 106 covering the titanium layer 105 is formed to cover the inner wall and bottom of the through hole 104 and the surface of the first insulating film 103. This deposition may be made by PVD or CVD.

Although the first barrier layer 107 is formed using titanium and titanium nitride in this embodiment, formation of the barrier layer is not limited to this material, but high melting point metals such as tantalum (Ta), ruthenium (Ru), and tungsten (W) and nitrides thereof may be used as the barrier layer.

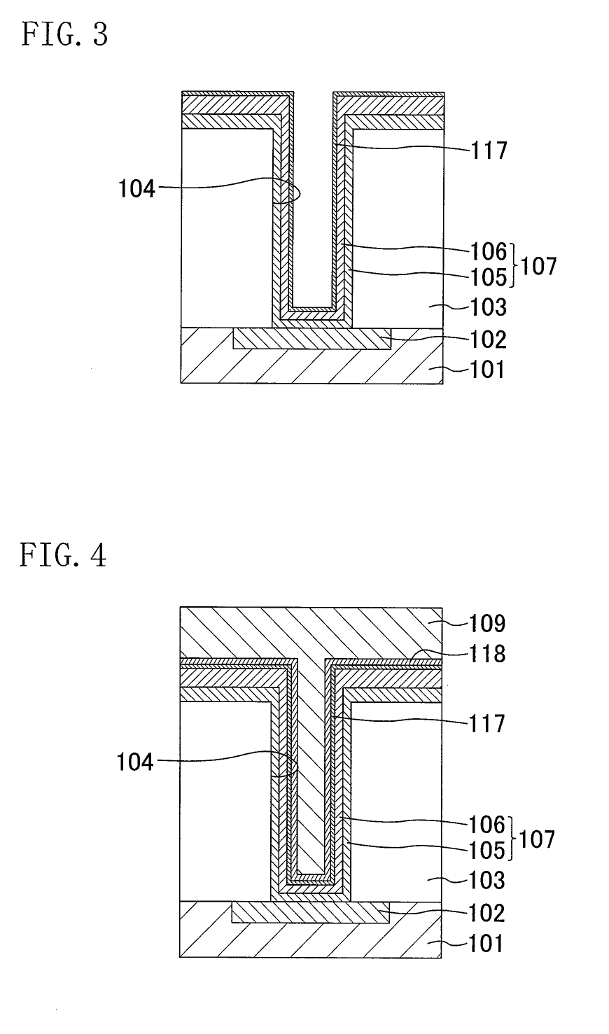

Thereafter, the step shown in FIG. 3 is executed, in which a titanium silicide nitride (TiSiN) layer 117 is formed on the surface of the titanium nitride layer 106 as the second barrier layer by heat treatment in a silane gas atmosphere.

The heat treatment for formation of the titanium silicide nitride layer 117 (second barrier layer) will be described. In this embodiment, silane is used as the atmosphere gas during the heat treatment. However, the atmosphere gas is not limited to this, but a similar effect can be obtained as long as the heat treatment is performed in an atmosphere of a silicon-system hydrogen compound gas such as disilane (Si₂H₆). On the contrary, the effect of this embodiment will not be obtained by heat treatment in an atmosphere of a boron-containing hydrogen compound such as diborane described in Document 1 or a phosphorus-containing hydrogen compound such as phosphine (PH₃). This is because, since boron-containing hydrogen compounds such as diborane and phosphorus-containing hydrogen compounds such as phosphine are high in reactivity with water, heat treatment in an atmosphere of such a gas will cause reaction of the atmosphere gas with water during the treatment. For this reason, it is advisable to use a gas low in reactivity with water, e.g., a silicon-system hydrogen compound gas, as the atmosphere gas during the heat treatment performed after formation of the first barrier layer 107.

It is also advisable to perform the heat treatment in a silane atmosphere at a temperature in the range from 100° C. to less than 450° C. If the heat treatment is performed at a temperature as high as 450° C. or more, the intermetallic compound layer 102 may undergo phase transformation, and this may possibly affect the transistor characteristics. Conversely, if heat treatment is performed at a temperature as low as less than 100° C., the titanium silicide nitride layer 117 (second barrier layer) may not be formed sufficiently on the titanium nitride layer 106 of the first barrier layer 107, failing to obtain the effect of reducing permeation of moisture detached from the first insulating film 103 sufficiently. For these reasons, the heat treatment temperature is set in the range from 100° C. to less than 450° C.

A treatment time of one minute or less can be enough to obtain a sufficient effect from the heat treatment in a silane atmosphere. Conversely, if the heat treatment is performed for a long time exceeding one minute, the titanium silicide nitride layer 117 (second barrier layer) will be formed excessively, causing increase in contact resistance. Accordingly, the heat treatment time in a silane atmosphere is set at one minute or less. A sufficient effect can be obtained with a treatment time of about 30 seconds.

Continuity between the step of forming the first barrier layer 107 and the step of forming the second barrier layer (titanium silicide nitride layer 117) is as follows. After formation of the first barrier layer 107, the process may proceed to the heat treatment for formation of the second barrier layer continuously without exposure to the atmosphere, or exposure to the atmosphere may follow after formation of the first barrier layer 107 and then the second barrier layer may be formed.

Subsequent to the formation of the titanium silicide nitride layer 117 shown in FIG. 3, the process proceeds to the step shown in FIG. 4 without exposure to the atmosphere. In this step, a boron-containing tungsten film 118 is formed on the surface of the titanium silicide nitride layer 117 (second barrier layer) as a nucleation layer by CVD or ALD with diborane gas reduction of tungsten hexafluoride. Subsequently, a tungsten layer 109 is formed to cover the boron-containing tungsten film 118 by CVD. Thus, the through hole 104 is filled with the tungsten layer 109 as a conductive film via the first barrier layer 107, the titanium silicide nitride layer 117 as the second barrier layer, and the boron-containing tungsten film 118.

Continuity between the heat treatment step for formation of the titanium silicide nitride layer and the step of forming the boron-containing tungsten film 118 as the nucleation layer is as follows. As one method, it is desirable to execute the heat treatment in a silane atmosphere and the deposition of the boron-containing tungsten film 118 in the same reaction chamber. Alternatively, when the two operations are executed in separate reaction chambers, it is desirable to transport the semiconductor substrate 101 from a reaction chamber for the heat treatment to another reaction chamber for the deposition of the nucleation layer under high vacuum without being exposed to the atmosphere after the heat treatment.

If the semiconductor substrate 101 is exposed to the atmosphere after the heat treatment, moisture will adsorb to the titanium silicide nitride layer 117. Such moisture may react with diborane during formation of the boron-containing tungsten film 118, causing increase in contact resistance value. Accordingly, by allowing the process to proceed to the step of forming the boron-containing tungsten film 118 after the heat treatment without being exposed to the atmosphere, increase in contact resistance value can be suppressed.

Thereafter, the step shown in FIG. 5 is executed. First, portions of the first barrier layer 107, the titanium silicide nitride layer 117, the boron-containing tungsten film 118, and the tungsten layer 109 protruding over the first insulating film 103 shown in FIG. 4 are removed by CMP, to form a contact 110 in the through hole 104.

Thereafter, a second insulating film 111 is formed covering the first insulating film 103 and the contact 110, and then a third insulating film 112 is formed covering the second insulating film 111. An opening is then formed through the second and third insulating films 111 and 112 to expose the top surface of the contact 110, and inside the opening, formed is a first interconnect layer 116 constructed of a barrier layer 113, a seed layer 114, and a copper layer 115. This may be performed using any of lithography, dry etching, wet etching, PVD, CVD, electrolytic plating, CMP, and the like appropriately. Although not shown, another insulating film, an upper connection hole, and an upper interconnect layer are also formed above the first interconnect layer 116.

The semiconductor device 100 of this embodiment is fabricated in the manner described above. Contact resistance values of the semiconductor device 100 are shown in FIG. 6.

In FIG. 6, B represents contact resistance values of the semiconductor device 100 of this embodiment. That is, B represents the case where an O₃-TEOS film is used as the first insulating film 103, heat treatment is performed in a silane gas atmosphere after deposition of the first barrier layer 107 forming the titanium silicide nitride layer 117, and then the boron-containing tungsten film 118 is deposited using diborane gas.

A represents a comparative example, in which specifically heat treatment is performed in a diborane atmosphere after deposition of the first barrier layer 107, and then the boron-containing tungsten film is formed by ALD with diborane reduction. This involves no formation of an equivalent of the titanium silicide nitride layer 117.

As is apparent from FIG. 6, in the case B as this embodiment, increase in contact resistance value is suppressed and variations in contact resistance value are small. This is presumably because occurrence of reaction of diborane with moisture is avoided during deposition of the boron-containing tungsten film 118 as the nucleation layer, to ensure normal formation of the boron-containing tungsten film 118. More specifically, by changing the atmosphere gas during heat treatment after formation of the first barrier layer 107 to silane gas, reaction of the atmosphere gas with detached moisture from the first insulating film 103 is avoided. Also, by forming the titanium silicide nitride layer 117 on the surface of the titanium nitride layer 106 of the first barrier layer 107 as the second barrier layer, the barrier capability improves, reducing permeation of detached moisture from the first insulating film 103 through the barrier layer.

It is expected that the effect of this embodiment described above is exerted independent of the size of the contact 110. Therefore, the disclosed technique is especially effective for a contact having a diameter as fine as 60 nm or less with which increase in contact resistance value generally becomes prominent with miniaturization.

As shown in FIG. 15, it was clarified that a titanium nitride film having a thickness of 5.0 nm was necessary to avoid reaction of diborane gas with moisture. On the contrary, B in FIG. 6 represents the case where the thickness of the titanium nitride layer 106 is 2.6 nm in the semiconductor device 100 of this embodiment, and in this case, also, no increase in contact resistance value occurs.

The above fact indicates that the titanium nitride layer 106 of the first barrier layer 107 can be thinned even when the boron-containing tungsten film 118 is used as the nucleation layer, and moreover, with this structure, the contact resistance can be reduced compared with the conventional case. Specifically, the total thickness of the first and second barrier layers can be less than 5.0 nm.

In the semiconductor device 100 of this embodiment, the boron-containing tungsten film 118 can be used as the nucleation layer while reaction with moisture is avoided. Therefore, in comparison with the related art formation of the tungsten nucleation layer with silane reduction, the nucleation layer can be thinned. With this thinning, also, the contact resistance in the semiconductor device 100 can be reduced.

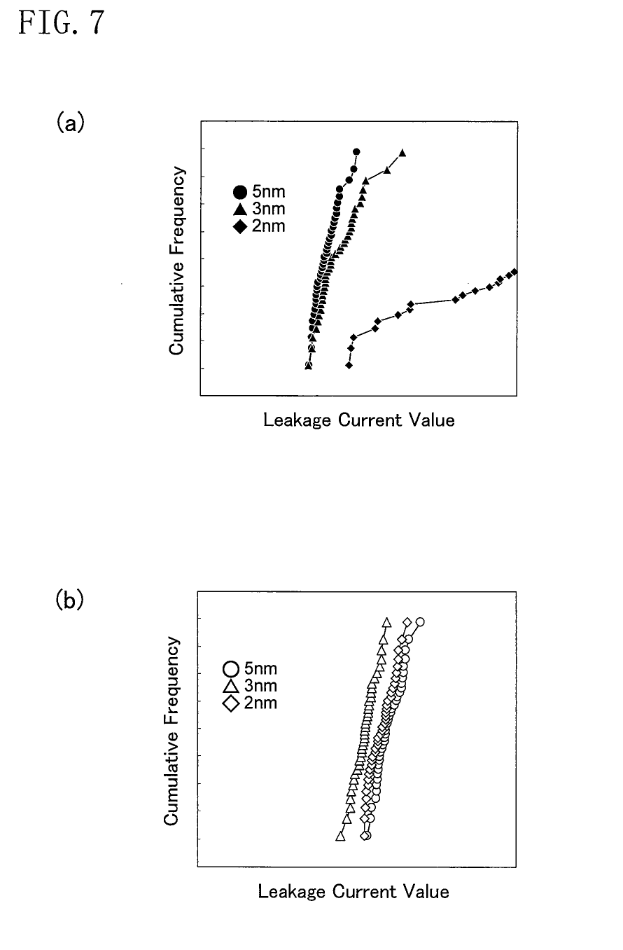

FIGS. 7(a) and 7(b) respectively show junction leakage currents observed in a comparative example (where the tungsten nucleation layer is deposited by ALD with silane reduction) and a case adopting this embodiment (where the boron-containing tungsten film formed by ALD with diborane reduction is used as the nucleation layer).

In the case of FIG. 7(a) as the comparative example, the junction leakage current increases when the thickness of the nucleation layer is reduced to as small as 2 nm. In contrast to this, in the case of FIG. 7(b) adopting this embodiment, no remarkable increase in junction leakage is observed even when the thickness of the nucleation layer is reduced to as small as 2 nm.

From the above results, it is found that while a thickness of 3 nm or more is necessary for the nucleation layer with silane reduction in the comparative example, the boron-containing tungsten film adopting this embodiment functions as the nucleation layer even with a thickness of 2 nm.

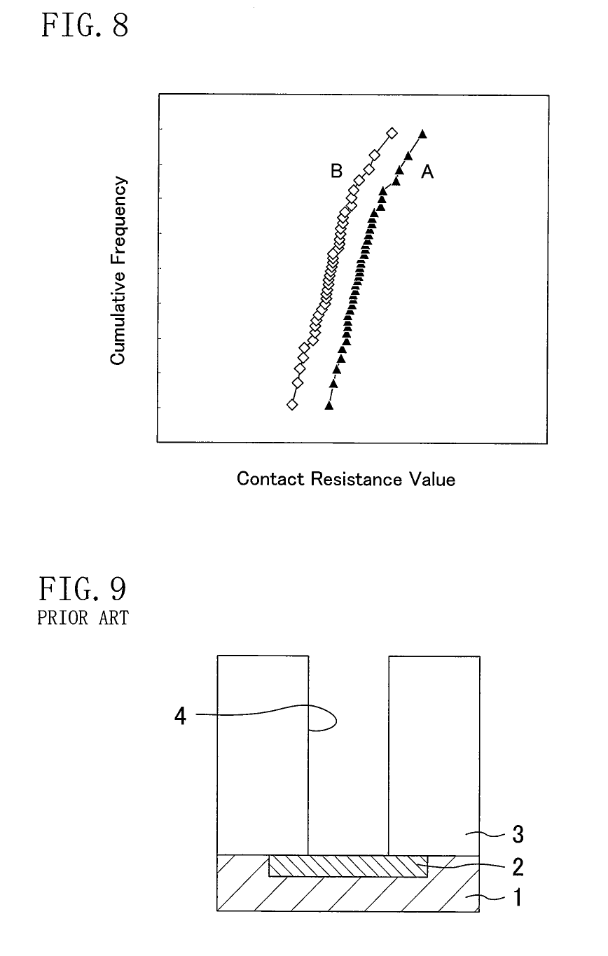

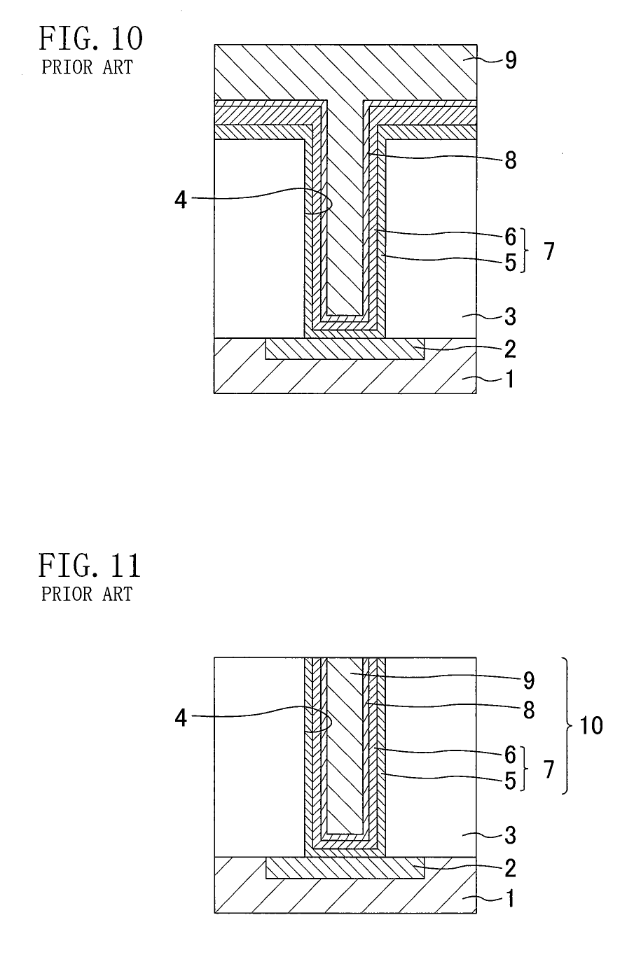

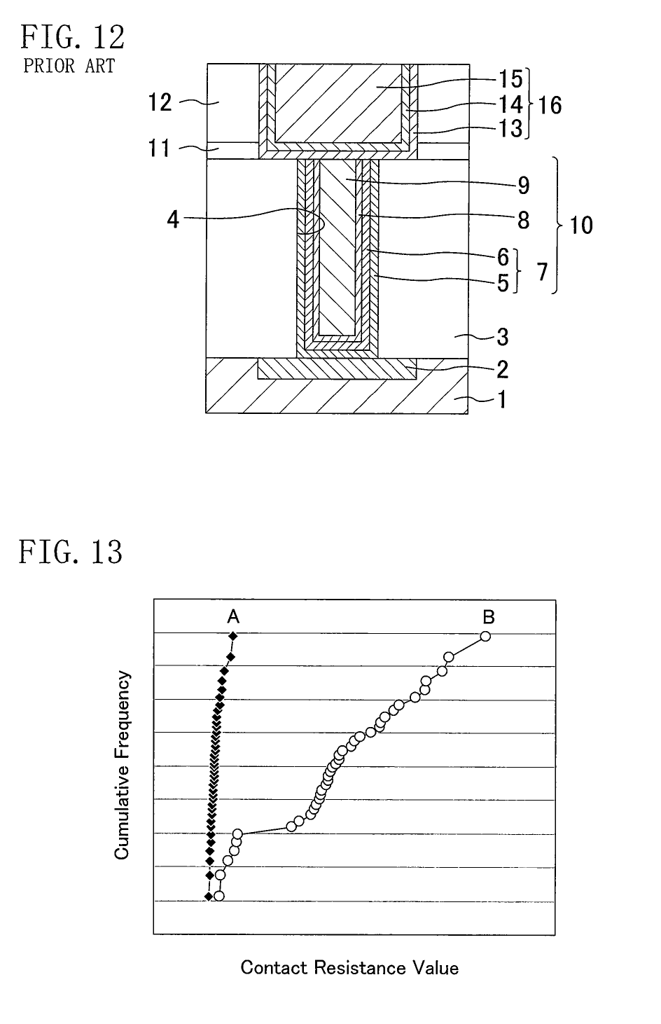

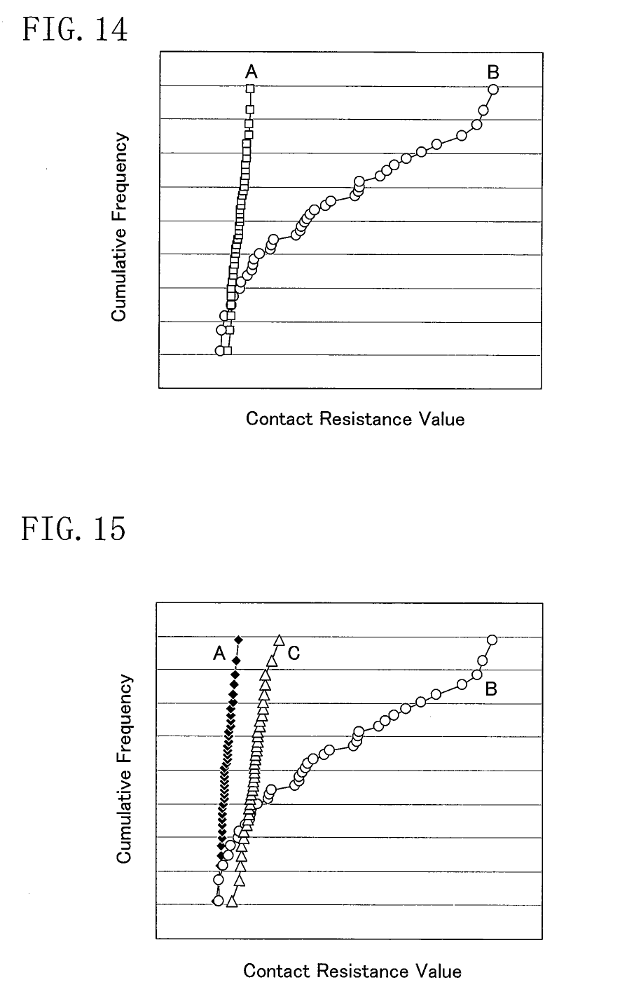

FIG. 8 shows contact resistance values obtained in the case of using a tungsten nucleation layer having a thickness of 3 nm formed by ALD with silane reduction (comparative example, represented by A) and in the case of using a boron-containing tungsten film having a thickness of 2 nm formed by ALD with diborane reduction as in this embodiment (represented by B). As is apparent from FIG. 8, the contact resistance is reduced in the case adopting this embodiment compared with the comparative example.

As described above, in the semiconductor device 100 of this embodiment, the boron-containing tungsten film can work as the nucleation layer without reacting with moisture. Also, the nucleation layer itself can be thinned, and thus the contact resistance value can be reduced compared with the conventional case.

Although the titanium silicide nitride layer has been described in this embodiment as the second barrier layer, the second barrier layer is not limited to this, but any film capable of reducing permeation of moisture can be used. For example, Ta, Ru, WN, and the like may be used.

According to the semiconductor device and the method for fabricating the same described above, increase in contact resistance value can be suppressed, and hence the present disclosure is useful for highly miniaturized semiconductor devices.

What is claimed is:

1. A semiconductor device, comprising:
a first insulting film formed on a semiconductor substrate, a contact hole being formed through the first insulating film to reach the semiconductor substrate;
a contact having a conductive film filling the contact hole;
a first barrier layer including a high melting point metal, formed between the semiconductor substrate and the conductive film and between the first insulating film and the conductive film; and
a second barrier layer lower in moisture permeability than the first barrier layer, formed between the first barrier layer and the conductive film.

2. The device of claim 1, further comprising:
a second insulting film formed on the first insulating film; and
an interconnect formed through the second insulting film to be connected to the contact.

3. The device of claim 1, wherein
the second barrier layer is a film including a compound of the high melting point metal and silicon.

4. The device of claim 1, wherein
a layer including a compound of a major component of the conductive film and boron is formed between the second barrier layer and the conductive film.

5. The device of claim 4, wherein
the major component of the conductive film is tungsten.

6. The device of claim 1, wherein
the first barrier layer includes at least one of titanium, tantalum, ruthenium, and tungsten or a nitride thereof.

7. The device of claim 1, wherein
there is a position where the total thickness of the first barrier layer and the second barrier layer is less than 5.0 nm.

8. The device of claim 1, wherein
the first insulating film contains moisture.

9. The device of claim 1, wherein
the first insulating film is high in hygroscopicity compared with the second insulating film.

10. The device of claim 1, wherein
the diameter of the contact is 60 nm or less.

11. A method for fabricating a semiconductor device, comprising the steps of:
(a) forming a first insulting film on a semiconductor substrate;
(b) forming a contact hole through the first insulating film to reach the semiconductor substrate;
(c) forming a first barrier layer including a high melting point metal to cover the bottom and sidewall of the contact hole;
(d) forming a second barrier layer lower in moisture permeability than the first barrier layer to cover the first barrier layer; and
(e) filling the contact hole with a conductive film after the step (d).

12. The method of claim 11, wherein
the second barrier layer is a film including a compound of the high melting point metal and silicon.

13. The method of claim 11, wherein
the second barrier layer is formed by heat-treating the first barrier layer in a silicon-containing hydrogen compound atmosphere.

14. The method of claim 11, further comprising the step of:
(f) forming a layer including a compound of a major component of the conductive film and boron on the second barrier layer, between the step (d) and the step (e).

15. The method of claim 14, wherein
the step (d) and the step (f) are performed while keeping the semiconductor substrate from exposure to the atmosphere.

16. The method of claim 11, wherein
the major component of the conductive film is tungsten.

17. The method of claim 11, wherein
the first barrier layer includes at least one of titanium, tantalum, ruthenium, and tungsten or a nitride thereof.

18. The method of claim 11, wherein
there is a position where the total thickness of the first barrier layer and the second barrier layer is less than 5.0 nm.

19. The method of claim 11, wherein
the first insulating film contains moisture.

20. The method of claim 11, wherein
the first insulating film is high in hygroscopicity compared with the second insulating film.

21. The method of claim 11, wherein
the diameter of the contact is 60 nm or less.

22. The method of claim 11, wherein
in the step (d), the semiconductor substrate is held at a temperature in a predetermined temperature range for one minute or less.

23. The method of claim 22, wherein
the predetermined temperature range is from 100° C. to less than 450° C.
